(19) United States
(12) Patent Application Publication
(10) Pub. No.: US 2012/0111264 A1
(43) Pub. Date: May 10, 2012

(54) METHOD FOR PRODUCING GROUP III METAL NITRIDE SINGLE CRYSTAL

(76) Inventors: Takanao Shimodaira, Nagoya-city (JP); Katsuhiro Imai, Nagoya-city (JP); Makoto Iwai, Kasugai-city (JP)

(21) Appl. No.: 13/344,809

(22) Filed: Jan. 6, 2012

Related U.S. Application Data
(63) Continuation of application No. PCT/JP2010/061740, filed on Jul. 6, 2010.

(30) Foreign Application Priority Data
Jul. 7, 2009 (JP) 2009-161000

(51) Int. Cl. C30B 9/04

(52) U.S. Cl. 117/78

(57) ABSTRACT

A plurality of seed crystal films of a single crystal of a nitride of a metal belonging to group III are formed on a substrate, while a non-growth surface not covered with the seed crystal films is formed on the substrate. A single crystal of a nitride of a metal belonging to group III is grown on the seed crystal film. A plurality of the seed crystal films are separated by the non-growth surface and arranged in at least two directions X and Y. The maximum inscribed circle diameter “A” of the seed crystal film is 50 μm or more and 6 mm or less, a circumscribed circle diameter “B” of the seed crystal film is 50 μm or more and 10 mm or less, and the maximum inscribed circle diameter “C” of the non-growth surface 1b is 100 μm or more and 1 mm or less.

This application is a Continuation under 35 U.S.C. §120 to PCT Patent Application No. PCT/JP2010/061740, filed Jul. 6, 2010, which claims priority under 35 U.S.C. §119 to Japanese Patent Application No. 2009-161000, filed Jul. 7, 2009, the entireties of which are incorporated by reference herein.

### TECHNICAL FIELD OF THE INVENTION

The present invention relates to a method for growing a nitride single crystal of a metal belonging to group III.

### BACKGROUND ARTS

Gallium nitride thin film crystal draws attention as excellent blue light-emitting devices, has been used as a material for light-emitting diodes and expected as a blue-violet semiconductor laser device for an optical pickup.

According to Japanese Patent Publication No. 2004-247711A, uneven pattern is formed in a surface of a template substrate to provide a seed substrate to grow GaN by Na flux method. After that, the thus region grown by flux method is separated (peeled off) from the temperate in the vicinity of spaces formed by recesses.

According to Japanese Patent publication No. 2005-12171A, spaces are formed in a seed crystal film on a surface of a template substrate, and it is grown a nitride single crystal of a metal belonging to group III on the seed crystal by means of flux method.

Further, according to Japanese Patent Publication No. 2008-239365A, a surface of a sapphire substrate is processed to form island-shaped regions, seed crystal films are formed on surfaces of the islands-shaped regions, and it is formed a nitride single crystal of a metal belonging to group III on the seed crystal film by flux method.

According to Japanese Patent Publication No. 2009-120465A, masks of a width (or diameter) of 10 to 100 μm are formed on an underlying substrate at an interval of 250 to 2000 μm, and GaN crystal is grown on the substrate by vapor phase deposition.

According to Japanese Patent Publication No. 2004-182551A, many seed crystal parts are formed on a surface of an underlying substrate, and gallium nitride single crystal is then grown thereon by vapor phase process.

According to FIG. 11 and (0058) of Japanese Patent Publication No. 2001-267243A, many island-shaped steps are formed on a substrate, and it is formed thereon a nitride single crystal of a metal belonging to group III by vapor phase process.

### DISCLOSURE OF THE INVENTION

As described above, it is described, in Japanese Patent Publication Nos. 2004-247711A, 2005-12171A and 2008-239365A, a method of forming seed crystal films, for example of a shape of a band, on a substrate, forming non-grown surfaces on the substrate between the adjacent seed crystal films, and forming a nitride single crystal of a metal of group III is formed by flux method. Further, according to Japanese Patent Publication Nos. 2009-120465A and 2004-182551A, a nitride single crystal of a metal belonging to group III is formed by vapor phase process on seed crystal films. Further, according to Japanese Patent Publication No. 2001-267243A, many island-shaped seed crystal films are formed on a substrate, and it is formed thereon a nitride single crystal of a metal of group III by vapor phase method.

However, as the inventors have further studied, when a nitride single crystal of a metal belonging to group III is grown by flux method and then cooled, it is proved that the single crystal cannot be often peeled off the substrate and the peeling of the film over the whole of the surface of the single crystal is particularly difficult. Further, cracks may occur in the grown nitride single crystal of a metal belonging to group III to result in defective products.

An object of the present invention is, in forming a plurality of seed crystal films on a substrate and growing a nitride single crystal of a metal belonging to group III by flux method on the seed crystal films, to facilitate the separation of the grown single crystal from the substrate and to reduce cracks in the single crystal.

The present invention provides a method comprising the steps of:

forming a plurality of seed crystal films of a single crystal of a nitride of a metal belonging to group III on a substrate, while a non-growth surface is formed on the substrate, the surface being not covered with the seed crystal films; and

growing a single crystal of a nitride of a metal belonging to group III on the seed crystal film by flux method;

wherein a plurality of the seed crystal films are separated by the non-growth surface and arranged in at least two directions;

wherein the maximum inscribed circle diameter of the seed crystal film is 50 μm or more and 6 mm or less;

wherein a circumscribed circle diameter of the seed crystal film is 50 μm or more and 10 mm or less; and

wherein the maximum inscribed circle diameter of the non-growth surface is 100 μm or more and 1 mm or less.

According to the present invention, the separation of the nitride single crystal of a metal belonging to group III grown by flux method from the substrate is facilitated and natural separation can be easily caused. In addition to this, it is proved that cracks in the grown single crystal can be reduced.

According to Japanese Patent Publication Nos. 2004-247711A, 2005-12171A and 2008-239365A, it is not described that the seed crystal films are arranged in at least two directions as the present invention.

According to Japanese Patent Publication Nos. 2009-120465A, 2004-182551A and 2001-267243A, a nitride single crystal of a metal of group III is formed by vapor phase process. Therefore, it is required that a width of each seed crystal film and spacing between the adjacent seed crystal films are 1 μm or so. If the width of the seed crystal film and the spacing is larger than that, integrated film-formation is impossible so that it is fundamentally different from the present invention.

### BRIEF DESCRIPTION OF THE DRAWINGS

FIG. 1 is a plan view schematically showing planar pattern of seed crystal films 3A on a substrate 1.

FIG. 2 is a plan view schematically showing planar pattern of seed crystal films 3B on a substrate 1.

FIG. 3 is a plan view schematically showing planar pattern of seed crystal films 3C on a substrate 1.

FIG. 4 is a plan view schematically showing planar pattern of seed crystal films 3A on a substrate 1.

FIG. 5 is a plan view schematically showing planar pattern of seed crystal films 3D on a substrate 1.

FIG. 6(a) is a cross sectional view schematically showing the state in which seed crystal films 2 are formed on a surface 1a of a substrate 1, and FIG. 6(b) is a cross sectional view schematically showing the state in which seed crystal films 3 separated from each other are formed.

FIG. 7(a) is a cross sectional view schematically showing the state in which a nitride single crystal 4 of a metal belonging to group III is formed on the seed crystal film 3 of FIG. 6 by flux method, and FIG. 7(b) is a cross sectional view schematically showing the state in which the seed crystal film 4 is separated from the substrate 1.

FIG. 8(a) is a cross sectional view schematically showing the state in which seed crystal films 2 are formed on a surface 1a of a substrate 1, and FIG. 8(b) is a cross sectional view schematically showing the state in which recesses 5 and seed crystal films 3 separated from each other are formed.

FIG. 9(a) is a cross sectional view schematically showing the state in which a nitride single crystal 4 of a metal belonging to group III is formed on the seed crystal film 3 of FIG. 8 by flux method, and FIG. 9(b) is a cross sectional view schematically showing the state in which the seed crystal film 4 is separated from the substrate 1.

### BEST MODES FOR CARRYING OUT THE INVENTION

The present invention will be described in detail below, with reference to the accompanying drawings.

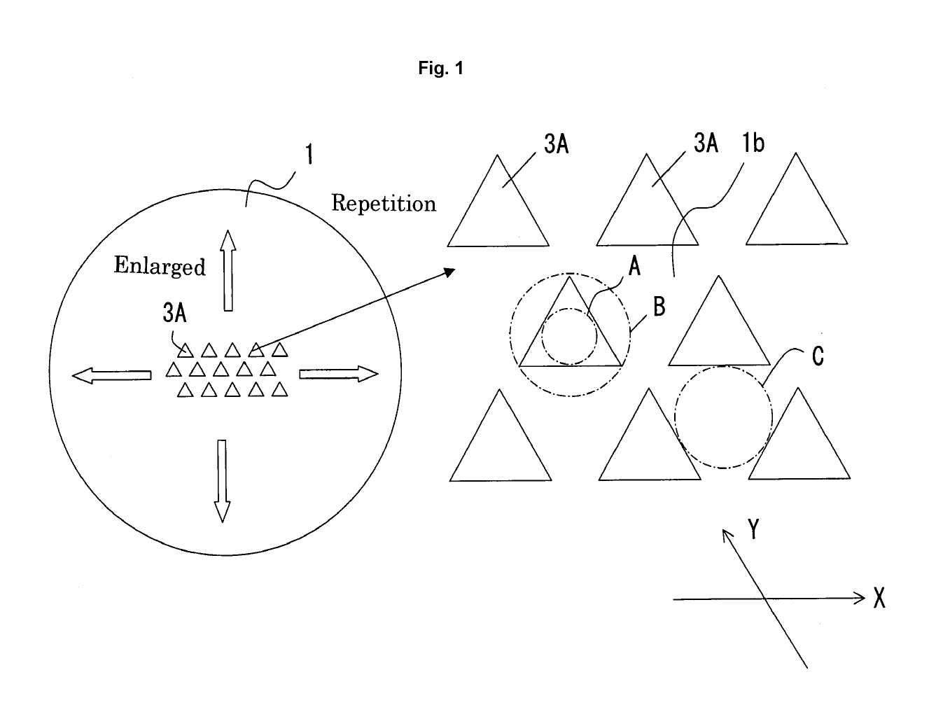

According to the present invention, as shown in FIG. 1 for example, a plurality of seed crystal films 3A are formed on a surface of a substrate 1. The seed crystal films 3A are separated from each other, and a surfaces 1b not for growth formed between the seed crystal films 3A. The seed crystal films 3A are arranged in horizontal direction “X” in FIG. 1 at a constant interval and in an inclined direction “Y” at a constant interval.

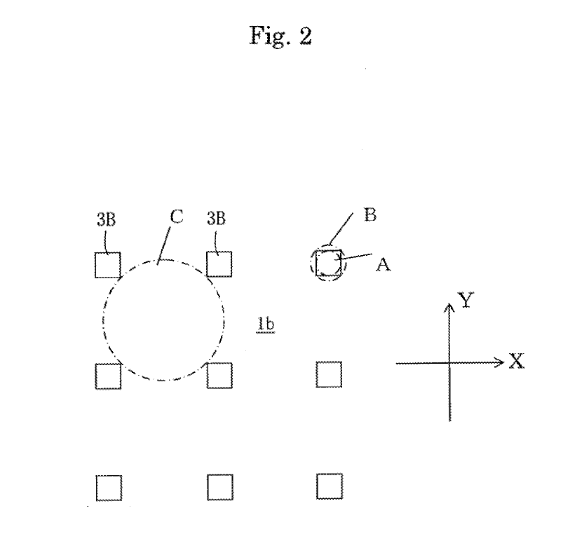

According to an example of FIG. 2, a plurality of tetragonal seed crystal films 3B are formed on a surface of a substrate 1. The seed crystal films 3B are separated from each other, and a non-growth surface 1b is formed between the seed crystal films 3B. The seed crystal films 3B are arranged in horizontal direction “X” in FIG. 2 at a constant interval and in vertical direction “Y” at a constant interval.

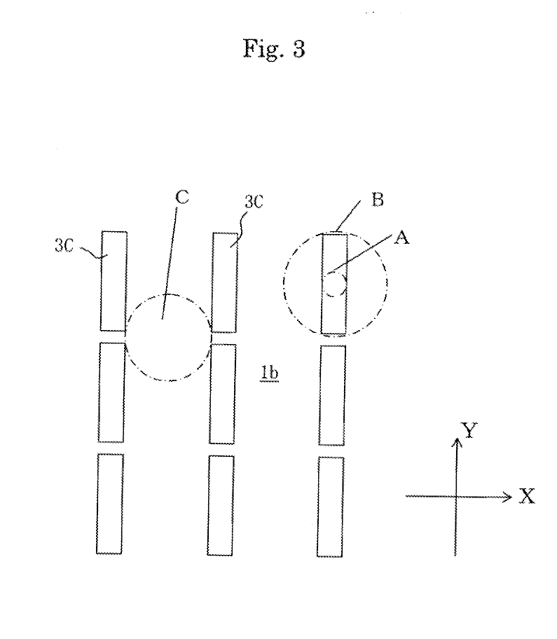

According to an example of FIG. 3, a plurality of band-shaped or rectangular seed crystal films 3C are formed on a surface of a substrate 1. The seed crystal films 3C are separated from each other, and a non-growth surface 1b is formed between the seed crystal films 3C. The seed crystal films 3C are arranged in horizontal direction “X” in FIG. 3 as a constant interval and in vertical direction “Y” at a constant interval.

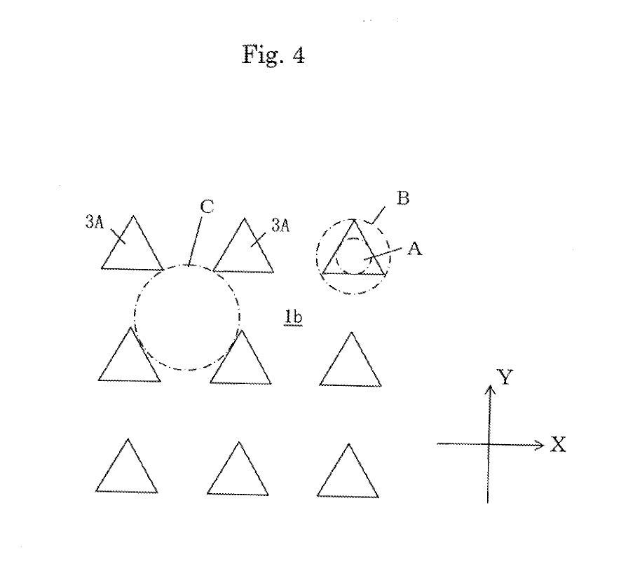

According to an example of FIG. 4, a plurality of triangle seed crystal films 3C are formed on a surface of a substrate 1. The seed crystal films 3C are separated from each other, and a non-growth surface 1b is formed between the seed crystal films 3C. The seed crystal films 3C are arranged in horizontal direction “X” in FIG. 4 at a constant interval and in vertical direction “Y” at a constant interval.

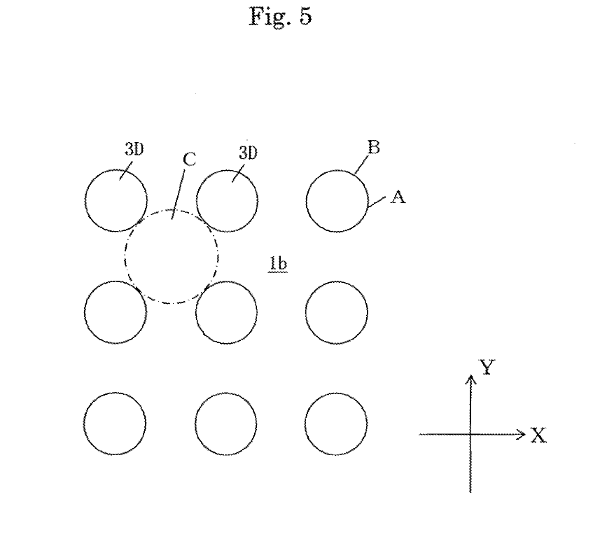

According to an example of FIG. 5, a plurality of circular seed crystal films 3D are formed on a surface of a substrate 1. The seed crystal films 3D are separated from each other, and a non-growth surfaces 1b is formed between the seed crystal films 3D. The seed crystal films 3D are arranged in horizontal direction “X” in FIG. 5 at a constant interval and in vertical direction “Y” at a constant interval.

According to the present invention, the seed crystal films are arranged in at least two directions “X” and “Y”. Here, it is sufficient that the X-axis and Y-axis are intersected with each other (refer to FIG. 1), and it is not required that they are crossed at the right angle. However, an angle at which the X-axis and Y-axis are crossed may preferably by 40 to 140° and more preferably be 45 to 135°.

In each of the directions of X-axis and Y-axis, although the pitch of the seed crystal films may preferably be constant, it is not required that the pitch is constant.

According to the present invention, the maximum inscribed circle diameter of the seed crystal films 3A to 3D is 50 μm or more and 6 mm or less.

In the case that the maximum inscribed circle diameter “A” of the seed crystal films 3A to 3D is less than 50 μm, when the nitride single crystal of a metal belonging to group III is grown by flux method, melt-back of the seed crystal films into flux may occur to prevent the growth of the single crystal thereon so that an integrated and self-standing single crystal film cannot be obtained. On the viewpoint, the maximum inscribed circle diameter “A” of the seed crystal films 3A to 3D may preferably be 100 μm or more. In the case that the nitride single crystal of a metal belonging to group III is formed by vapor phase process, such problem is not caused, and rather an integrated single crystal film cannot be formed when “A” becomes larger.

In the case that the maximum inscribed circle diameter “A” of the seed crystal films 3A to 3D exceeds 6 mm, cracks are generated in the grown single crystal. On the viewpoint, the maximum inscribed circle diameter “A” of the seed crystal films 3A to 3D may preferably be 1 mm or less and more preferably be 500 m or less.

Further, according to the present invention, the circumscribed circle diameter “B” is 50 μm or more and 10 mm or less.

In the case that the circumscribed circle diameter “B” of the seed crystal films 3A to 3D is less than 50 μm, when the nitride single crystal of a metal belonging to group III is grown by flux method, melt-back of the seed crystal films into flux may occur to prevent the growth of the single crystal thereon so that an integrated and self-standing single crystal film cannot be obtained. On the viewpoint, the circumscribed circle diameter “B” of the seed crystal films 3A to 3D may preferably be 100 μm or more.

In the case that the circumscribed circle diameter “B” of the seed crystal films 3A to 3D exceeds 10 mm, cracks are generated in the grown single crystal. On the viewpoint, the circumscribed circle diameter “B” of the seed crystal films 3A to 3D may preferably be 7 mm or less.

Further, according to the present invention, the maximum inscribed circle diameter “C” of the non-growth surface between the seed crystal films 3A to 3D is 100 μm or more and 1 mm or less. In the case that the maximum inscribed circle diameter “C” of the non-growth surface between the seed crystal films 3A to 3D is less than 100 μm, cracks tend to occur in the grown single crystal. On the viewpoint, the maximum inscribed circle diameter “C” of the non-growth surface between the seed crystal films 3A to 3D may more preferably be 200 μm or more.

In the case that the maximum inscribed circle diameter of the non-growth surface between the seed crystal films 3A to 3D exceeds 1 mm, cracks tend to be generated in the grown single crystal. On the viewpoint, the maximum inscribed circle diameter of the non-growth surface between the seed crystal films 3A to 3D may more preferably be 700 μm or less.

The planar shape of the seed crystal film may be a curved figure such as circle, ellipse and race-track shape, or a polygon such as stars, triangle, square, hexagon or the like.

The non-growth surface means a surface on which the single crystal 4 does not grow. Specifically, the non-growth surface is an exposed surface of the substrate, or a surface of another film (such as thin film layer of an oxide) formed on a substrate.

Next, shapes of the seed crystal film and non-growth surface are examplified.

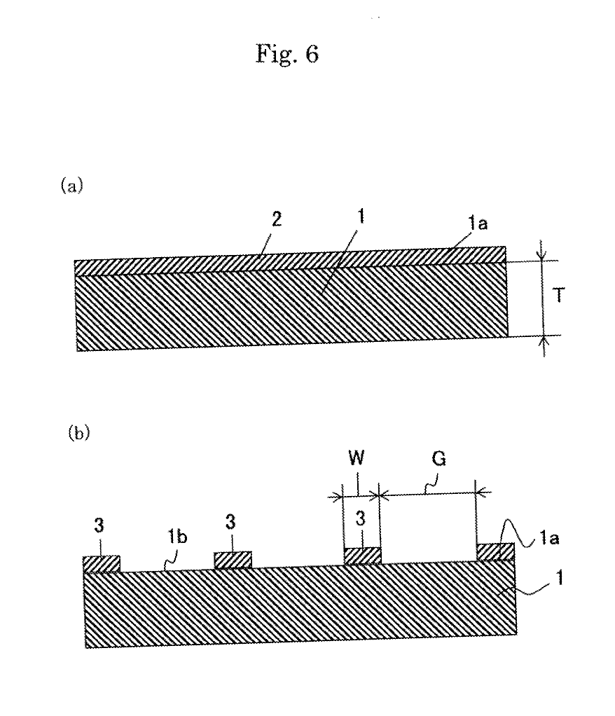

As shown in FIG. 6(a), the surface 1a of the substrate 1 is smoothly processed, so that a well aligned seed crystal film 2 is formed on the surface 1a.

Then, as shown in FIG. 6(b), the seed crystal film 2 is processed to form a plurality of seed crystal films 3 separated from each other. A non-growth surface 1b is formed between the adjacent seed crystal films 3.

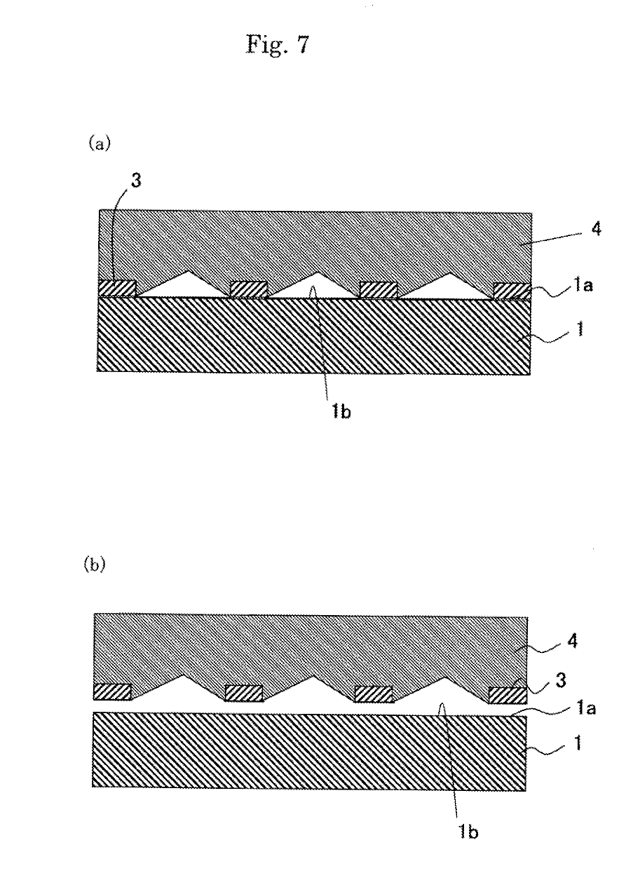

Then, as shown in FIG. 7(a), a nitride single crystal 4 of a metal belonging to group III is formed on the seed crystal films 3 by flux method. According to this step, the single crystals 4 formed on the adjacent seed crystal films 3 are connected with each other to cover the substrate 1.

Then, during temperature descending step after the growth of the single crystal 4, as shown in FIG. 7(b), the single crystal 4 is naturally, or easily by a small labor cost, from the template substrate 1, so that its productivity can be considerably improved.

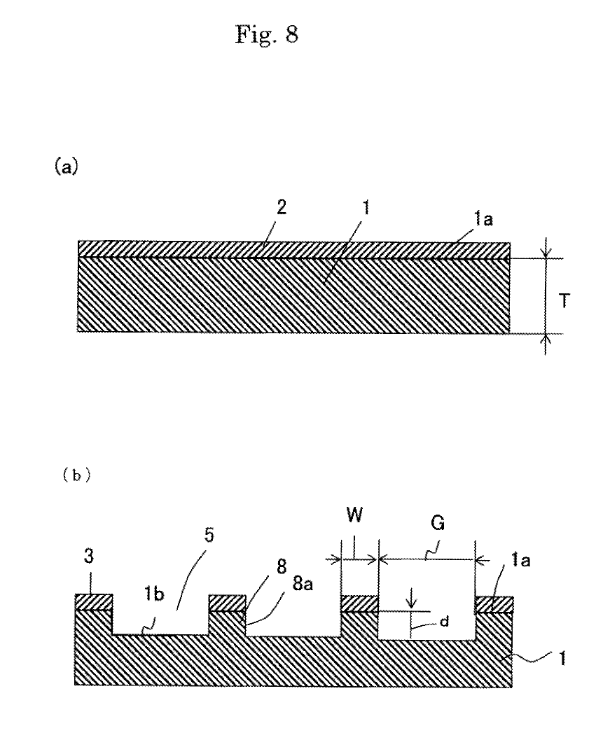

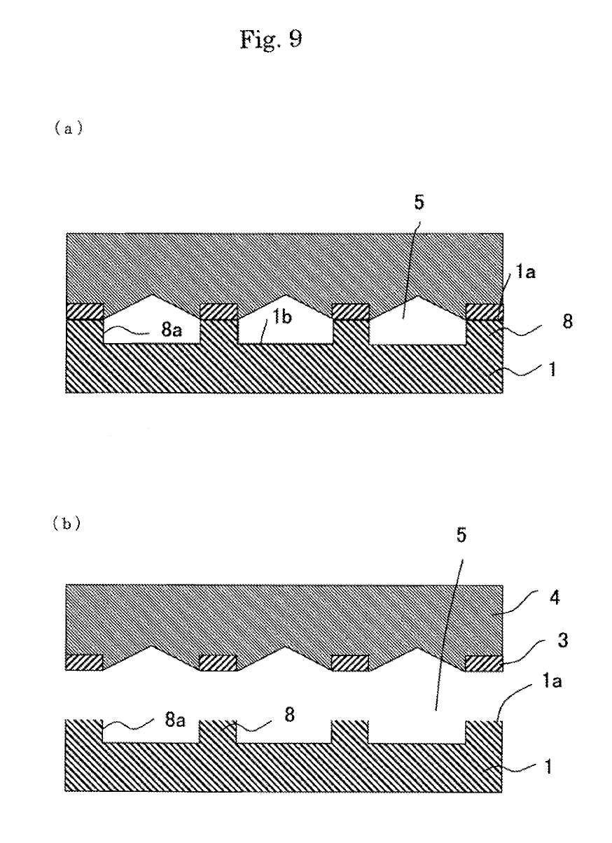

FIGS. 8 and 9 relate to another embodiment. As shown in FIG. 8(a), a surface 1a of a substrate 1 is processed into a smooth surface. A seed crystal film 2 is formed on the surface 1a. Then, the surface 1a of the substrate 1 is processed to form a plurality of seed crystal films 3 separated from each other, as shown in FIG. 8(b). However, according to the present example, the surface 1a of the substrate is further processed toward the inside to form recesses 5. The seed crystal films 3 are left on protrusions 8 between the recesses 5. On the protrusion 8, a film-forming surface 1a is left and a side wall face 8a is formed. The side wall face 8a and a bottom face 1b of the recess are formed as processed faces formed by the processing.

Then, as shown in FIG. 9(a), a nitride single crystal 4 of a metal belonging to group III is formed on the seed crystal film 3 by flux method. According to this step, the single crystals 4 formed on the adjacent seed crystal films 3 are connected with each other to cover the substrate 1.

Then, during the temperature descending step after the growth of the single crystal 4, as shown in FIG. 9(b), the single crystal 4 is naturally, or easily by a small labor cost, from the template substrate 1, so that its productivity can be considerably improved.

The thickness “T” of the substrate 1 (refer to FIGS. 6 and 8) may preferably be 0.8 mm or more and 1.2 mm or less, so as to facilitate the natural separation of the single crystal from the substrate. On the viewpoint, the thickness “T” of the substrate may more preferably be 0.9 mm or more, and more preferably be 1.1 μm or less.

Preferably, an angle θ of the longitudinal direction of the side wall face 8a of the protrusion 8 and a-axis of the substrate may be 25° or less and more preferably 20° or less, and still more preferably 10° or less. Most preferably, the longitudinal direction of the side wall face of the protrusion and a-axis of the substrate main body is parallel with each other.

Here, the a-axis means [symbol] 1 −2 0 [symbol] of hexagonal single crystal. As both of sapphire and gallium nitride are hexagonal, a1, a2 and a3 are equivalent, and six axes of [2 −1 −1 0], [1 1 −2 0], [−1 2 −1 0], [−2 1 1 0], [−1 −1 2 0] and [1 −2 1 0] are equivalent. Among the six, a-axis is commonly represented by [1 1 −2 0] , and a-axis referred to in the specification means the above equivalent axes, so that the representation of [1 1 −2 0] includes all the above equivalent axes representations.

The material of the substrate is not particularly limited, and examples of such material include sapphire, silicon single crystal, SiC single crystal, MgO single crystal, spinel (MgAl₂O₄), LiAlO₂, LiGaO₂, and perovskite composite oxides such as LaAlO₃, LaGaO₃ and NdGaO₃. Also, it is possible to use cubic perovskite structure composite oxides represented by the composition formula [A_{1-y}(Sr₁₋ₓBaₓ)_{y}] [(Al_{1-z}Ga_{z})₁₋ᵤ.Dᵤ]O₃ (where A is a rare-earth element, D is one or more elements selected from the group consisting of niobium and tantalum, y=0.3 to 0.98, x=0 to 1, z=0 to 1, u=0.15 to 0.49, and x+z=0.1 to 2). In addition, SCAM (ScAlMgO₄) may be also used.

The method of forming the non-growth surface 1b is not particularly limited. Particularly, it is possible to produce a deep groove (with a depth of 10 μm or more), which is difficult to produce by lithography, by processing of groove-formation by sand blasting at a low cost. Further, it is sufficient that the processed surface is smooth, leaves processing distortion and is not epi-ready (that is, it has a surface state on which GaN thin film is not grown). For example, laser processing, plasma etching and dicing (with diamond blade) may be used.

The depth “d” of the recess 5 shown in FIGS. 8(b) and 9(b) may preferably be 100 μm or less, more preferably be 1 μm or less and most preferably be 0.1 μm or less, on the viewpoint of facilitating the separation of the grown single crystal and of preventing crack generation in the substrate 1 starting from the recess. When alumina abrasive grain of number 600 to 800 is used in the sand blasting, the processing rate of a sapphire substrate is smaller by several tens times than that of GaN thin film, so that it is preferred for adjusting the depth of the recess.

The single crystal of the nitride of a metal belonging to the group III forming the seed crystal film is a nitride of one or more metal selected from the group consisting of Ga, Al and In, and includes GaN, AlN, GaAlN, GaAlInN and the like. It may preferably be GaN, AlN or GaAlN.

The method of forming the seed crystal films may preferably be MOCVD process on the viewpoint of controlling concentrations of impurities and uniformity of film thickness.

The thickness of the seed crystal film is not particularly limited. On the viewpoint of preventing melt-back of the seed crystal film, the thickness may preferably be 1 μm or more and more preferably be 5 μm or more. Further, since it is required more time to form an underlying film as the underlying film is thicker, the thickness may preferably be smaller as far as the melt-back is prevented. On the viewpoint, the thickness of the seed crystal film may preferably be 30 μm or less.

Then, the nitride single crystal of a metal belonging to group III is grown on the seed crystals by flux method.

As long as the group III metal nitride single crystal can be generated, a type of the flux is not particularly limited. In a preferred embodiment, the flux containing at least one of an alkaline metal and an alkaline-earth metal is used, and the flux containing sodium metal may be particularly preferably used.

As to the flux, raw materials of the group III metal nitride single crystal to be desired are mixed and used. The single crystal of the nitride of a metal belonging to the group III is the nitride of one or more metal selected from the group consisting of Ga, Al, In and B, and includes GaN, AlN, GaAlN, GaAlInN, BN and the like. It is preferably GaN or GaAlN.

The materials for forming the flux is selected depending on the target single crystal of a nitride of a metal belonging to group III

As gallium raw materials, for example, gallium single metal, a gallium alloy or a gallium compound may be used; in terms of handling, gallium single metal may be used preferably.

As aluminum raw materials, aluminum single metal, an aluminum alloy or an aluminum compound may be used; in terms of handling, aluminum single metal may be used preferably.

As indium raw materials, indium single metal, an indium alloy or an indium compound may be used; in terms of handling, indium single metal may be used preferably.

The growth temperature of the group III nitride single crystal in the flux method and the holding time during the growth are not particularly limited, and they are appropriately changed in accordance with a type of the single crystal to be desired or a composition of the flux. As an example, when GaN single crystal is grown using a flux containing sodium or lithium, the growth temperature may be set to 800° C. to 1000° C.

According to a preferred embodiment, the single crystal of the nitride of a metal belonging to the group III is grown in atmosphere of mixed gases containing nitrogen gas. Although the total pressure of the atmosphere is not particularly limited, it may be preferably set to 10 atms or more, and further preferably 30 atm or more, on the viewpoint of prevention against the evaporation of the flux. However, as the pressure is high, an apparatus becomes large. Therefore, the total pressure of the atmosphere may be preferably set to 200 atms or less, and further preferably 100 atms or less.

Further, although the nitrogen partial pressure in the atmosphere is not particularly limited, it may preferably be 10 to 200 atms and more preferably be 30 to 100 atms in the case that gallium nitride is grown. In the case that aluminum nitride is grown, it may preferably be 0.1 to 50 atms and more preferably be 1 to 10 atms.

Any other gas except the nitrogen-containing gas in the atmosphere is not limited; but an inert gas may be preferably used, and argon, helium, or neon may be particularly preferably used. The partial pressure of such gas other than nitrogen is a value obtained by subtracting the nitrogen partial pressure from the total pressure.

Actual growing method is not particularly limited in the present invention. For example, the template substrate may be immersed in flux in a crucible contained in a pressure vessel and heated while nitrogen-containing atmosphere is supplied into the pressure vessel. Further, the template substrate may be fixed at a predetermined position and the crucible containing flux may be moved upwardly, so that the surface of the underlying film is brought into contact with the flux.

### EXAMPLES

### Inventive Example 1

Gallium nitride single crystal was grown according to the method described referring to FIGS. 8 and 9.

Specifically, on a surface 1a of a c-face sapphire substrate 1 having a diameter of 4 inches and thickness of 0.8 mm, a GaN low-temperature buffer layer was formed at 550° C. to 70 nm. Thereafter, a GaN thin film 2 having a thickness of 8 micron was formed at 1050° C. by vapor phase process. The surface of the GaN template was processed by sand blasting. The processing was performed until the GsN thin film was diminished and the sapphire substrate surface was exposed. The depth of processing was made 8 μm. Further, the GaN thin film in a circumferential region of 1.5 mm was removed by sand blasting at the same time.

However, the planar shapes of the protrusions and seed crystal films 3D formed on the substrate were made circular shape as shown in FIG. 5, and many circular seed crystal films 3D were arranged in directions of X axis and Y axis. The maximum inscribed circle diameter “A” of the seed crystal film 3D was made 50 μm, the circumscribed circle diameter “B” was made 50 μm, and the maximum inscribed circle diameter “C” of the non-growth surface was made 500 μm.

Then, GaN single crystal was grown on the template substrate by flux method. Specifically, in a glove box filled with argon atmosphere, the GaN template of φ4 inches with the processed groove was placed as a seed crystal substrate in center of the bottom of a growing container having an inner diameter of φ120 mm. Further, 130 g of metal sodium, 90 g of metal gallium and 350 mg of carbon were filled in the growing container. After the growing container is contained and sealed in a container made of a heat-resistant metal, it was mounted on a table capable of shaking and rotating in a crystal growing furnace. Nitrogen gas was supplied for pressurizing at 4.5 MPa while the temperature was raised to 870° C., and the flux melt was held for 100 hours while the flux melt was stirred by shaking and rotating to grow a crystal. Thereafter, the temperature was lowered to room temperature over 30 hours. Thereafter, the growing container was drawn out of the furnace for crystal growth, and ethanol was used to remove the flux to collect a plate of the thus grown nitride single crystal.

The thus obtained gallium nitride single crystal plate was separated from the sapphire substrate over the whole surface, was self-standing and free of cracks. The diameter was φ4 inches and the thickness was about 1.5 mm.

### Inventive Example 2

Gallium nitride single crystal was grown according to the same procedure as the inventive example 1. However, the shape of the seed crystal films 3C was made that as shown in FIG. 3, and many rectangular seed crystal films 3C were arranged in directions of X-axis and Y-axis. The maximum inscribed circle diameter “A” of the seed crystal film 3C was made 50 μm, the circumscribed circle diameter “B” was made 10 μm, and the maximum inscribed circle diameter “C” of the non-growth surface 1b was made 500 μm.

The thus obtained gallium nitride single crystal plate was separated from the sapphire substrate over the whole surface, was self-standing and free of cracks. The diameter was φ4 inches and the thickness was about 1.5 mm.

### Inventive Example 3

Gallium nitride single crystal was grown according to the same procedure as the inventive example 1. However, the shape of the seed crystal films 3C was made that as shown in FIG. 3, and many rectangular seed crystal films 3C were arranged in directions of X-axis and Y-axis. The maximum inscribed circle diameter “A” of the seed crystal film 3C was made 6 mm, the circumscribed circle diameter “B” was made 10 mm, and the maximum inscribed circle diameter “C” of the non-growth surface 1b was made 500 μm.

The thus obtained gallium nitride single crystal plate was separated from the sapphire substrate over the whole surface, was self-standing and free of cracks. The diameter was φ4 inches and the thickness was about 1.5 mm.

### Inventive Example 4

Gallium nitride single crystal was grown according to the same procedure as the inventive example 1. However, the shape of the seed crystal films 3C was made that as shown in FIG. 3, and many rectangular seed crystal films 3C were arranged in directions of X-axis and Y-axis. The maximum inscribed circle diameter “A” of the seed crystal film 3C was made 1 mm, the circumscribed circle diameter “B” was made 6 mm, and the maximum inscribed circle diameter “C” of the non-growth surface 1b was made 500 μm.

The thus obtained gallium nitride single crystal plate was separated from the sapphire substrate over the whole surface, was self-standing and free of cracks. The diameter was φ4 inches and the thickness was about 1.5 mm.

### Inventive Example 5

Gallium nitride single crystal was grown according to the same procedure as the inventive example 1. However, the shape of the seed crystal films 3C was made that as shown in FIG. 3, and many rectangular seed crystal films 3C were arranged in directions of X-axis and Y-axis. The maximum inscribed circle diameter “A” of the seed crystal film 3C was made 1 mm, the circumscribed circle diameter “B” was made 6 mm, and the maximum inscribed circle diameter “C” of the non-growth surface 1b was made 100 μm.

The thus obtained gallium nitride single crystal plate was separated from the sapphire substrate over the whole surface, was self-standing and free of cracks. The diameter was φ4 inches and the thickness was about 1.5 mm.

### Inventive Example 6

Gallium nitride single crystal was grown according to the same procedure as the inventive example 1. However, the shape of the seed crystal films 3C was made that as shown in FIG. 3, and many rectangular seed crystal films 3C were arranged in directions of X-axis and Y-axis. The maximum inscribed circle diameter “A” of the seed crystal film 3C was made 1 mm, the circumscribed circle diameter “B” was made 6 mm, and the maximum inscribed circle diameter “C” of the non-growth surface 1b was made 1 mm.

The thus obtained gallium nitride single crystal plate was separated from the sapphire substrate over the whole surface, was self-standing and free of cracks. The diameter was φ4 inches and the thickness was about 1.5 mm.

### Comparative Example 1

Gallium nitride single crystal was grown according to the same procedure as the inventive example 1. However, the shape of the seed crystal films 3C was made that as shown in FIG. 3, and many rectangular seed crystal films 3C were arranged in directions of X-axis and Y-axis. The maximum inscribed circle diameter “A” of the seed crystal film 3C was made 10 μm, the circumscribed circle diameter “B” was made 6 mm, and the maximum inscribed circle diameter “C” of the non-growth surface 1b was made 500 μm.

As a result, a part of the GaN thin film was melted back and GaN single crystal was not grown on such part.

### Comparative Example 2

Gallium nitride single crystal was grown according to the same procedure as the inventive example 1. However, the shape of the seed crystal films 3C was made that as shown in FIG. 3, and many rectangular seed crystal films 3C were arranged in directions of X-axis and Y-axis. The maximum inscribed circle diameter “A” of the seed crystal film 3C was made 1 mm, the circumscribed circle diameter “B” was made 15 mm, and the maximum inscribed circle diameter “C” of the non-growth surface 1b was made 500 μm.

The thus obtained plate of gallium nitride crystal had a diameter of φ4 inches and a thickness of about 1.5 mm, and cracks were observed by eyes.

### Comparative Example 3

Gallium nitride single crystal was grown according to the same procedure as the inventive example 1. However, the shape of the seed crystal films 3C was made that as shown in FIG. 3, and many rectangular seed crystal films 3C were arranged in directions of X-axis and Y-axis. The maximum inscribed circle diameter “A” of the seed crystal film 3C was made 1 mm, the circumscribed circle diameter “B” was made 6 mm, and the maximum inscribed circle diameter “C” of the non-growth surface 1b was made 50 μm.

The thus obtained plate of gallium nitride crystal had a diameter of φ4 inches and a thickness of about 1.5 mm, and cracks were observed by eyes.

### Comparative Example 4

Gallium nitride single crystal was grown according to the same procedure as the inventive example 1. However, the shape of the seed crystal films 3C was made that as shown in FIG. 3, and many rectangular seed crystal films 3C were arranged in directions of X-axis and Y-axis. The maximum inscribed circle diameter “A” of the seed crystal film 3C was made 1 mm, the circumscribed circle diameter “B” was made 6 mm, and the maximum inscribed circle diameter “C” of the non-growth surface 1b was made 1.6 mm.

The thus obtained plate of gallium nitride crystal had a diameter of φ4 inches and a thickness of about 1.5 mm, and cracks were observed by eyes.

### Comparative Example 5

Gallium nitride single crystal was grown according to the same procedure as the inventive example 1. However, the shape of the seed crystal films 3C was made that as shown in FIG. 3, and many rectangular seed crystal films 3C were arranged in directions of X-axis and Y-axis. The maximum inscribed circle diameter “A” of the seed crystal film 3C was made 8 mm, the circumscribed circle diameter “B” was made 15 mm, and the maximum inscribed circle diameter “C” of the non-growth surface 1b was made 500 μm.

The thus obtained plate of gallium nitride crystal had a diameter of φ4 inches and a thickness of about 1.5 mm, and cracks were observed by eyes.

Experimental results are summarized and shown in the following tables 1, 2 and 3.

However, the tables show the shapes of the seed crystal films (circular, elliptical or rectangular).

Further, each item of the experimental results shown in the tables is as follows.

GaN crystal plate was self-standing without cracks.

“Cracks” Cracks were generated in GaN crystal plate.

“Melt-back” GaN thin film was melted back during crystal growth.

“Inventive, comparative” Results correspond with inventive and comparative examples.

Although the present invention has been described with reference to particular embodiments, the invention is not limited thereto and various changes and modification may be made without departing from the scope of the appended claims.

TABLE 1

| Maximum | Circumscribed | | | | | | | |
|---|---|---|---|---|---|---|---|---|
| inscribed circle | circle diameter | | Maximum inscribed circle diameter of protrusion | | | | | |
| diameter of recess | of protrusion | | 10 μm | 50 μm | 500 μm | 1 mm | 6 mm | 8 mm |
| 50 μm | 10 | μm | circular: | | | | | |
| | | | melt-back | | | | | |
| 50 μm | 50 | μm | rectangular: | circular: | | | | |
| | | | melt-back | cracks | | | | |
| 50 μm | 1 | mm | rectangular: | rectangular: | rectangular: | | | |
| | | | melt-back | cracks | cracks | | | |
| 50 μm | 6 | mm | rectangular: | rectangular: | rectangular: | rectangular: | | |
| | | | melt-back | cracks | cracks | cracks | | |
| | | | | | | Comparative 3 | | |
| 50 μm | 8 | mm | rectangular: | rectangular: | rectangular: | rectangular: | | |
| | | | melt-back | cracks | cracks | cracks | | |
| 50 μm | 10 | mm | rectangular: | rectangular: | rectangular: | rectangular: | rectangular: | |
| | | | melt-back | cracks | cracks | cracks | cracks | |
| 50 μm | 15 | mm | rectangular: | rectangular: | rectangular: | rectangular: | rectangular: | rectangular: |
| | | | melt-back | cracks | cracks | cracks | cracks | cracks |
| 100 μm | 10 | μm | circular: | | | | | |
| | | | melt-back | | | | | |
| 100 μm | 50 | μm | rectangular: | circular: ◯ | | | | |
| | | | melt-back | | | | | |
| 100 μm | 1 | mm | rectangular: | rectangular: ◯ | rectangular: ◯ | | | |
| | | | melt-back | | | | | |
| 100 μm | 6 | mm | rectangular: | rectangular: ◯ | rectangular: ◯ | rectangular: ◯ | | |
| | | | melt-back | | | Inventive 5 | | |
| 100 μm | 8 | mm | rectangular: | rectangular: ◯ | rectangular: ◯ | rectangular: ◯ | | |
| | | | melt-back | | | | | |
| 100 μm | 10 | mm | rectangular: | rectangular: ◯ | rectangular: ◯ | rectangular: ◯ | rectangular: ◯ | |
| | | | melt-back | | | | | |
| 100 μm | 15 | mm | rectangular: | rectangular: | rectangular: | rectangular: | rectangular: | rectangular: |
| | | | melt-back | cracks | cracks | cracks | cracks | cracks |

TABLE 2

| Maximum | Circumscribed | | | | | | | |
|---|---|---|---|---|---|---|---|---|
| inscribed circle | circle diameter | | Maximum inscribed circle diameter of protrusion | | | | | |
| diameter of recess | of protrusion | | 10 μm | 50 μm | 500 μm | 1 mm | 6 mm | 8 mm |
| 200 μm | 10 | μm | circular: | | | | | |
| | | | melt-back | | | | | |
| 200 μm | 50 | μm | rectangular: | circular: ◯ | | | | |
| | | | melt-back | | | | | |
| 200 μm | 1 | mm | rectangular: | rectangular: ◯ | rectangular: ◯ | circular: ◯ | | |
| | | | melt-back | | | | | |
| 200 μm | 6 | mm | rectangular: | rectangular: ◯ | rectangular: ◯ | rectangular: ◯ | | |
| | | | melt-back | | | | | |
| 200 μm | 8 | mm | rectangular: | rectangular: ◯ | rectangular: ◯ | rectangular: ◯ | | |
| | | | melt-back | | | | | |
| 200 μm | 10 | mm | rectangular: | rectangular: ◯ | rectangular: ◯ | rectangular: ◯ | rectangular: ◯ | |
| | | | melt-back | | | | | |
| 200 μm | 15 | mm | rectangular: | rectangular: | rectangular: | rectangular: | rectangular: | rectangular: |
| | | | melt-back | cracks | cracks | cracks | cracks | cracks |
| 500 μm | 10 | μm | circular: | | | | | |
| | | | melt-back | | | | | |
| 500 μm | 50 | μm | rectangular: | circular: ◯ | | | | |
| | | | melt-back | Inventive 1 | | | | |
| 500 μm | 1 | mm | rectangular: | rectangular: ◯ | rectangular: ◯ | circular: ◯ | | |
| | | | melt-back | | | | | |
| 500 μm | 6 | mm | rectangular: | rectangular: ◯ | rectangular: ◯ | rectangular: ◯ | | |
| | | | melt-back | | | Inventive 4 | | |
| | | | Comparative 1 | | | | | |
| 500 μm | 8 | mm | rectangular: | rectangular: ◯ | rectangular: ◯ | rectangular: ◯ | | |
| | | | melt-back | | | | | |
| 500 μm | 10 | mm | rectangular: | rectangular: ◯ | rectangular: ◯ | rectangular: ◯ | rectangular: ◯ | |
| | | | melt-back | Inventive 2 | | | Inventive 3 | |
| 500 μm | 15 | mm | rectangular: | rectangular: | rectangular: | rectangular: | rectangular: | rectangular: |
| | | | melt-back | cracks | cracks | cracks | cracks | cracks |
| | | | | | | Comparative 2 | | |

TABLE 3

| Maximum | | Circumscribed | | | | | | | |
|---|---|---|---|---|---|---|---|---|---|
| inscribed circle | | circle diameter | | Maximum inscribed circle diameter of protrusion | | | | | |
| diameter of recess | | of protrusion | | 10 μm | 50 μm | 500 μm | 1 mm | 6 mm | 8 mm |
| 800 | μm | 10 | μm | circular: | | | | | |
| | | | | melt-back | | | | | |
| 800 | μm | 50 | μm | rectangular: | circular: ◯ | | | | |
| | | | | melt-back | | | | | |
| 800 | μm | 1 | mm | rectangular: | rectangular: ◯ | rectangular: ◯ | circular: ◯ | | |
| | | | | melt-back | | | | | |
| 800 | μm | 6 | mm | rectangular: | rectangular: ◯ | rectangular: ◯ | rectangular: ◯ | | |
| | | | | melt-back | | | | | |
| 800 | μm | 8 | mm | rectangular: | rectangular: ◯ | rectangular: ◯ | rectangular: ◯ | | |
| | | | | melt-back | | | | | |
| 800 | μm | 10 | mm | rectangular: | rectangular: ◯ | rectangular: ◯ | rectangular: ◯ | rectangular: ◯ | |
| | | | | melt-back | | | | | |
| 800 | μm | 15 | mm | rectangular: | rectangular: | rectangular: | rectangular: | rectangular: | rectangular: |
| | | | | melt-back | cracks | cracks | cracks | cracks | cracks |
| 1 | mm | 10 | μm | circular: | | | | | |
| | | | | melt-back | | | | | |
| 1 | mm | 50 | μm | rectangular: | circular: ◯ | | | | |
| | | | | melt-back | | | | | |
| 1 | mm | 1 | mm | rectangular: | rectangular: ◯ | rectangular: ◯ | circular: ◯ | | |
| | | | | melt-back | | | | | |
| 1 | mm | 6 | mm | rectangular: | rectangular: ◯ | rectangular: ◯ | rectangular: ◯ | circular: ◯ | |
| | | | | melt-back | | | Inventive 6 | | |
| 1 | mm | 8 | mm | Rectangular: | rectangular: ◯ | rectangular: ◯ | rectangular: ◯ | elliptical: ◯ | |
| | | | | melt-back | | | | | |
| 1 | mm | 10 | mm | rectangular: | rectangular: ◯ | rectangular: ◯ | rectangular: ◯ | rectangular: ◯ | |
| | | | | melt-back | | | | | |
| 1 | mm | 15 | mm | rectangular: | rectangular: | rectangular: | rectangular: | rectangular: | rectangular: |
| | | | | melt-back | cracks | cracks | cracks | cracks | cracks |
| 1.6 | mm | 10 | μm | circular: | | | | | |
| | | | | melt-back | | | | | |
| 1.6 | mm | 50 | μm | rectangular: | circular: | | | | |
| | | | | melt-back | cracks | | | | |
| 1.6 | mm | 1 | mm | rectangular: | rectangular: | rectangular: | circular: | | |
| | | | | melt-back | cracks | cracks | cracks | | |
| 1.6 | mm | 6 | mm | rectangular: | rectangular: | rectangular: | rectangular: | circular: | |
| | | | | melt-back | cracks | cracks | cracks | cracks | |
| | | | | | | | Comparative 4 | | |
| 1.6 | mm | 8 | mm | rectangular: | rectangular: | rectangular: | rectangular: | rectangular: | circular: |
| | | | | melt-back | cracks | cracks | cracks | cracks | cracks |
| 1.6 | mm | 10 | mm | rectangular: | rectangular: | rectangular: | rectangular: | rectangular: | elliptical: |
| | | | | melt-back | cracks | cracks | cracks | cracks | cracks |
| 1.6 | mm | 15 | mm | rectangular: | rectangular: | rectangular: | rectangular: | rectangular: | rectangular: |
| | | | | melt-back | cracks | cracks | cracks | cracks | cracks |

1. A method of producing a single crystal of a nitride of a metal belonging to group III, said method comprising the steps of
forming a plurality of seed crystal films of a single crystal of a nitride of a metal belonging to group III on a substrate, while forming a non-growth surface on said substrate, said non-growth surface being not covered with said seed crystal films; and
growing a single crystal of a nitride of a metal belonging to group III on said seed crystal films by flux method;
wherein a plurality of said seed crystal films are separated by said non-growth surface and arranged in at least two directions;
wherein the maximum inscribed circle diameter of said seed crystal film is 50 μm or more and 6 mm or less;
wherein a circumscribed circle diameter of said seed crystal film is 50 μm or more and 10 mm or less; and
wherein the maximum inscribed circle diameter of said non-growth surface is 100 μm or more and 1 mm or less.

2. The method of claim 1, wherein the maximum inscribed circle diameter of said seed crystal film is 50 μm or more and 1 mm or less;
wherein a circumscribed circle diameter of said seed crystal film is 50 μm or more and 10 mm or less; and
wherein the maximum inscribed circle diameter of said non-growth surface is 200 μm or more and 1 mm or less.

3. The method of claim 1, wherein the maximum inscribed circle diameter of said seed crystal film is 50 μm or more and 500 μm or less;
wherein a circumscribed circle diameter of said seed crystal film is 50 μm or more and 10 mm or less; and
wherein the maximum inscribed circle diameter of said non-growth surface is 200 μm or more and 1 mm or less.

4. The method of claim 1, wherein a recess is formed in said substrate and said non-growth surface is formed in said recess.

5. The method of claim 1, wherein at least one of said seed crystal films has a shape of a triangle or substantially triangular shape.

6. The method of claim 1, wherein at least one of said seed crystal films has a shape of a tetragon or substantially tetragonal shape.

7. The method of claim 1, wherein at least one of said seed crystal films has a shape of a circle or substantially circular shape.

8. The method of claim 1, wherein at least one of said seed crystal films has a shape of an ellipse or substantially elliptical shape.

9. The method of claim 1, wherein, in the step of growing, said nitride single crystals of a metal belonging to group III grown from the adjacent seed crystal films are associated with each other at the respective a-faces.

10. The method of claim 1, wherein said grown nitride single crystal of a metal belonging to group III comprises a single crystal of gallium nitride or aluminum nitride.

11. The method of claim 1, wherein said nitride single crystal of a metal belonging to group III forming said seed crystal film comprises a single crystal of gallium nitride, aluminum nitride or solid solution of aluminum nitride-gallium nitride.

12. The method of claim 1, wherein said grown nitride single crystal of a metal belonging to group III is separated naturally from said seed crystal film.
